(19) United States
(12) Patent Application Publication
(10) Pub. No.: US 2016/0285476 A1
(43) Pub. Date: Sep. 29, 2016

(54) METHOD FOR ENCODING AND DECODING OF DATA BASED ON BINARY REED-SOLOMON CODES

(71) Applicant: SHENZHEN CESTBON TECHNOLOGY CO. LIMITED, Shenzhen (CN)

(72) Inventors: Hui LI, Shenzhen (CN); Hanxu HOU, Shenzhen (CN); Jun CHEN, Shenzhen (CN); Bing ZHU, Shenzhen (CN); Shuoyan LI, Shenzhen (CN)

(21) Appl. No.: 15/173,712

(22) Filed: Jun. 5, 2016

Related U.S. Application Data
(63) Continuation-in-part of application No. PCT/CN2014/093964, filed on Dec. 16, 2014.

(51) Int. Cl. H03M 13/15; H03M 13/00; G06F 11/10

(52) U.S. Cl. CPC H03M 13/1515; G06F 11/1076; H03M 13/616

(57) ABSTRACT

A method for encoding and decoding of data based on binary Reed-Solomon codes. The method includes the steps of constructing binary Reed-Solomon codes from an original data using XOR operations, refreshing the binary Reed-Solomon codes using XOR operations, and reconstructing the binary Reed-Solomon codes using XOR operations.

### CROSS-REFERENCE TO RELATED APPLICATIONS

This application is a continuation-in-part of International Patent Application No. PCT/CN2014/093964 with an international filing date of Dec. 16, 2014, designating the United States, now pending, the contents of which are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, Mass. 02142.

### BACKGROUND OF THE INVENTION

1. Field of the Invention

The invention generally relates to the field of distributed storage systems, and more particularly to encoding and decoding of data based on binary Reed-Solomon (BRS) codes.

2. Description of the Related Art

The rapid development of computer network applications has brought forth an increasingly large amount of network information, which has made the task of storing such network information increasingly important. The growing demand for data storage has resulted in a rapid development of the entire storage industry. Distributed storage systems which feature high cost performance, low initial investment, and need-based payment have now become a mainstream technology in the field of large data storage.

A state of storage node failure is common in the field of distributed storage systems. Hence, redundancy must be introduced to improve reliability in case of storage node failure. One method for introducing the redundancy is data backup, which is simple but has low storage efficiency and system reliability. Another method for introducing the redundancy is coding, which improves storage efficiency. Thus coding is the key of the distributed storage system to improve availability, reliability, and security of the system. In the current storage systems, Maximum Distance Separable (MDS) code, which is optimal at storage space efficiency, is majorly employed for coding. A (n, k) MDS erasure code is configured to divide an original file into k equal sized modules, and generates n irrelevant coding modules via linear encoder, where n nodes are configured to store different modules so as to meet the MDS attribute (any k coding modules in n coding modules are able to reconstruct the original file).

When the storage node failure occurs, the redundancy amount needs to be maintained. Thus, it is necessary to restore the data in the failed storage node and store the data in a new node. This process is called a repairing process. During the repairing, Reed-Solomon Codes require downloading of the data from k storage nodes, recovering the original data, and subsequently coding the storage data in the failure nodes for the new node. When the original data varies, to ensure the conformity of the data, the redundant calibration data blocks need refreshing. This process is called refreshing.

Row Diagonal Parity (RDP) code, which is a simple erasure code does not involve a finite field, and requires no matrix. Also, two calibration data blocks can be generated by row and pandiagonal-based XOR algorithm. Thus, an erasure code having two calibration data blocks is produced. However, RDP code has high refreshing complexity and is inexpansible.

Cauchy Reed-Solomon (CRS) code is one of the most common Reed-Solomon codes and is widely used in the distributed storage system. For example, in Hadoop Distributed File System (HDFS), a CRS code based distributed storage system is provided but it has the following defects. Firstly, although the use of 0-1 to generate matrix can greatly reduce the complexity of coding and decoding, the decoding complexity is not optimal, and a plurality of erasure codes is involved. For example, RDP coding has higher decoding complexity than CRS. Secondly, the finite field binary matrix of CRS for coding and decoding is complex, and the 0 and 1 are discursive, which impedes the optimization of the coding and decoding. In addition, since the CRS has high coding complexity, when the data needs refreshing, it further increases the coding complexity.

### SUMMARY OF THE INVENTION

In view of the above described problems, one objective of the invention is to provide a method for constructing, reconstructing, and refreshing data based on a BRS code that ensures the redundancy of the system, effectively decreases the calculation amount in data refreshing, decreases the computational complexity in the decoding process, and improves the effectiveness (comprising the computation cost and the repairing time) in the repairing process after node failure.

To achieve the above objective, in accordance with one embodiment of the invention, there is provided a method for encoding and decoding of data based on binary Reed-Solomon codes. The method comprises constructing binary Reed-Solomon codes by original data using XOR operation, refreshing the binary Reed-Solomon codes using XOR operation, and reconstructing the binary Reed-Solomon codes using XOR operation.

In another embodiment, the original data includes k original data blocks wherein, each original data block has a length of L bit and is represented by sᵢ=s_{i,1}s_{i,2} . . . s_{i,L}, i=0, 1, 2, . . . , k−1. A parity data block mₐ is expressed by mₐ=s₀(r₀)⊕s₁(r₁)⊕ . . . ⊕sₖ₋₁(rₖ₋₁). A unique identifier of the parity data block ‘mₐ’ is expressed as ID_{α}=(r₀^{α}, r₁^{α}, . . . , rₖ₋₁^{α})=(0,α, 2α, . . . , (k−1)α), α=0,1,2, . . . , n−k−1. Further, the original data blocks and the parity data blocks are linearly independent from one another. Furthermore, the original data blocks are stored in system nodes and the parity data blocks are stored in verification nodes.

In yet another embodiment, the step of constructing comprises dividing the original data into k original data blocks, wherein each original data block contains L bits of data, and the k original data blocks are expressed by S=(s₀, s₁, . . . , sₖ₋₁). Further, constructing parity data blocks using M=(m₀, m₁, . . . ,mₙ₋ₖ₋₁),

$${m}_{i} = {\sum }_{j = 0}^{n - k - 1} {s}_{j} ( {r}_{j}^{i} ) , \\ i = 0 , 1 , … , k - 1 ,$$

in which rⱼⁱ represents a bit number of “0” added in front of sⱼ thereby forming the parity data blocks mᵢ, and rⱼⁱ is expressed as (r₀^{α}, r₁^{α}, r₂^{α}, . . . , rₖ₋₁^{α})=(0,α, 2α, . . . , (k−1)α), α=0,1,2, . . . , n−k−1. Furthermore, storing a total of N original data blocks with the parity data blocks to N nodes respectively, wherein the nodes Nᵢ(i=0,1, . . . , n−1) are stored with data s₀, s₁, s₂, . . ., sₖ₋₁, m₀, m₁, m₂, . . . ,mₙ₋ₖ₋₁ respectively, and the parity data blocks are acquired using XOR operation.

In yet another embodiment, the step of refreshing comprises refreshing a document and dividing the refreshed document into k original data blocks. Further, calculating a variable quantity of each data block by comparing the original data block derived after the refreshing, with the corresponding original data block derived before the refreshing. Furthermore, when the data block changes, adding a variable quantity to a corresponding position of each parity data block according to a redundant symbol, thereby refreshing the codes.

In yet another embodiment, the step of refreshing comprises maintaining a present status of the data block when the data block does not change.

In yet another embodiment, the step of reconstructing comprises collecting the original data blocks and/or the parity data blocks from arbitrary k nodes, and performing the XOR operation by cyclic iteration to decode the data.

The above objects and other objects, and features of the present invention are readily apparent from the following detailed description when read in connection with the accompanying drawings.

The method for encoding and decoding of data based on binary Reed-Solomon (BRS) codes is advantageous in greatly improving the upload rate and the download rate of the data, and decreases the operation complexity of the system to a large degree (such as the refreshment of the metadata and the broadcasting of the refreshed data). Further, the BRS code has high application value and development potential in the practical distributed storage system, and possesses an optimal encoding and decoding rate as well as the fastest refreshing speed. In case of huge data, the BRS code is able to finish the refreshment at a faster rate saving time and resources. Additionally, the cost is decreased and a good user experience is achieved.

Additionally, one ordinarily skilled in the art may understand and appreciate the above advantages, and additional advantages that are readily apparent from the following detailed description when read in connection with the accompanying drawings.

### BRIEF DESCRIPTION OF THE DRAWINGS

The invention is described with reference to the accompanying drawings, in which:

FIG. 1 is a schematic diagram of a method for encoding and decoding of data based on BRS codes in accordance with an exemplary embodiment of the invention;

FIG. 2 is a flow chart illustrating the constructing process of the BRS codes, in accordance with an exemplary embodiment; and

FIG. 3 is a flow chart illustrating the refreshing process of the BRS code, in accordance with an exemplary embodiment.

### DETAILED DESCRIPTION OF THE EMBODIMENTS

For further illustrating the invention, experiments detailing a method for encoding and decoding of data based on BRS codes is described below. It should be noted that the following examples are intended to describe and not to limit the invention.

Conventionally, Reed-Solomon code is based on finite field GF(q). In order to reduce the complexity of such Reed-Solomon code a binary Reed-Solomon code (BRS) is provided herein. In case of k original data blocks, where each original data block has a length of L bit, and assuming s_{i,j} represent a value of a j^{th} bit of a data block sᵢ, then sᵢ is represented as follows:

sᵢ=s_{i,1}s_{i,2} . . . s_{i,L}, i=0, 1, 2, . . . , k−1.

In case where n data blocks comprise the original data blocks and the parity data blocks, it is difficult to find n-k independent parity data blocks which are independent from one another to generate arbitrary k data blocks of n data blocks. In general, data blocks which satisfy the above conditions are called (n, k) independent.

In an embodiment, considering a document represented by S={s₀, s₁} as an example, and assuming the document comprises of two original data blocks s₀ and s₁, it is obvious that three linearly independent data blocks, namely, {s₀, s₁, s₀ ⊕s₁} exist based on XOR coding. However, this may not satisfy the demands of a distributed storage system. Hence one “0” bit is added to the head of the original data block s₀, and one “0” bit is added to the rear of the original data block where the original data block after the change is denoted as sᵢ(rᵢ), in which r is the bit number added to the head of the original data block sᵢ. For the above three data blocks, namely, {s₀, s₁, s₀ ⊕s₁} the original data blocks and the parity data blocks after the change are linearly independent from one another.

In an embodiment, the k original data blocks, where each of the k original data blocks having a length of L bits are represented by

sᵢ=s_{i,1}s_{i,2} . . . s_{i,L}, wherein i=0, 1, 2, . . . , k−1

Further a parity data block mₐ may be denoted by

mₐ=s₀(r₀)⊕s₁(r₁)⊕ . . . ⊕sₖ₋₁(rₖ₋₁)

Furthermore, a unique identifier of the parity data block mₐ may be denoted by

IDₐ=(r₀^{α}, r₁^{α}, . . . ,rₖ₋₁^{α})

In an embodiment, the construction of the identifier ID for encoding an arbitrary integral k is as follows:

The unique identifier of the parity data block represented by mₐ may be obtained using the following equation

ID_{α}=(r₀^{α}, r₁^{α}, . . . , rₖ₋₁^{α})=(0,α, 2α, . . . , (k−1)α), α=0,1,2, . . . , n−k−1

Thus, the n data blocks represented by

{s₀, s₁, . . ., sₖ₋₁, m₀, m₁, . . . , mₙ₋ₖ₋₁}.

Further, the n data blocks encoded by the above encoding method are linearly independent. For example, when k=4 and n=9, the coding identifiers are represented by

ID₁=(0,1, 2,3), ID₂=(0, 2, 4, 6), ID₃=(0,3, 6, 9), and ID₄=(0, 4,8,12),

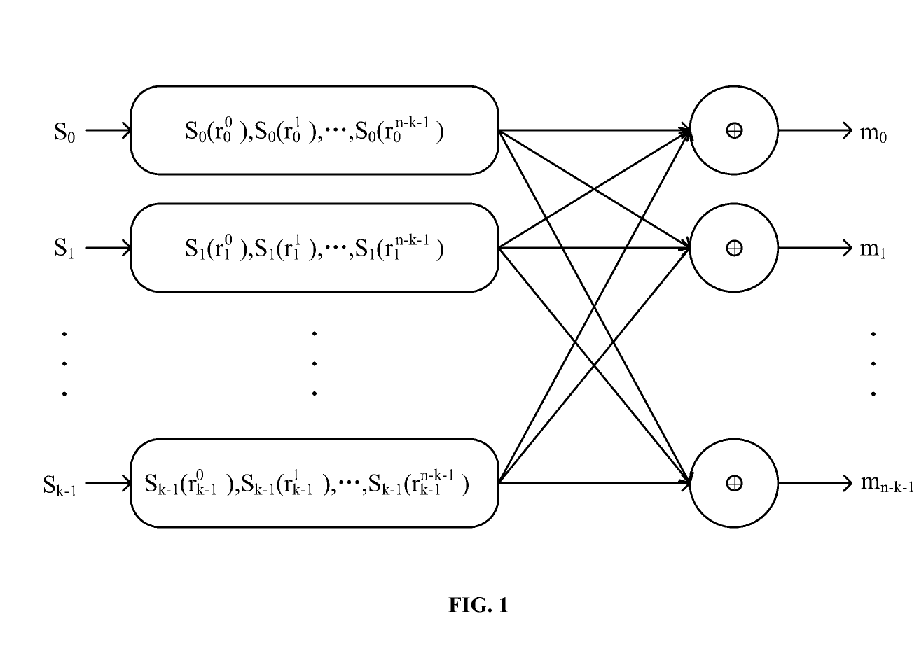

respectively. A whole encoding frame is illustrated in FIG. 1, in accordance with an exemplary embodiment.

The construction of the BRS code is disclosed in the instant embodiment. Generally, the Reed-Solomon code of a parameter represented by (n, k) comprises n nodes denoted as {N₀, N₁, . . . , Nₙ₋₁}. BRS codes are applied to the system comprising n nodes. Each node may be configured to store one original data block or one parity data block. Further, a single document may be uniformly divided into k original data blocks, which are stored in k nodes that may be referred to as system nodes. Additionally, the n−k parity data blocks generated by encoding are stored in the other n-k nodes which may be referred to as verification nodes.

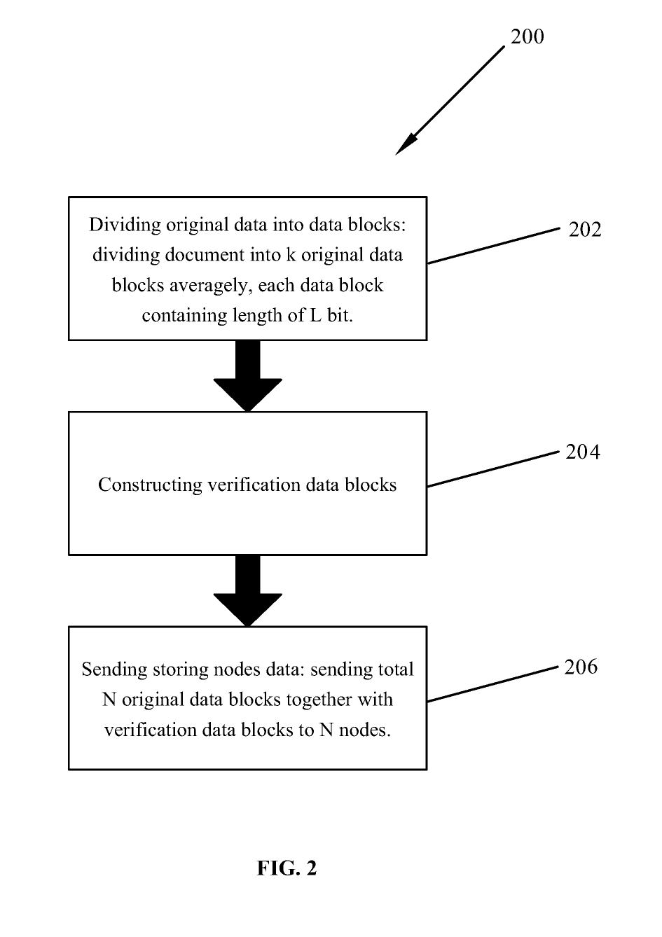

Further, FIG. 2 is a flow chart 200 illustrating a constructing process of the BRS codes, in accordance with an exemplary embodiment. At step 202, the original data is divided into k original data blocks, where each original data block may be of L bits in length. Further the data blocks are represented by S=(s₀, s₁, . . . sₖ₋₁).

At step 204, the parity data blocks are constructed as
M=(m₀, m₁, . . . , mₙ₋ₖ₋₁),

$${m}_{i} = {\sum }_{j = 0}^{n - k - 1} {s}_{j} ( {r}_{j}^{i} ) ,$$

i=0 ,1, . . . , k−1, in which rⱼⁱ represents the bit number of “0” added in front of the original data block represented by sⱼ so as to form the parity data block mᵢ. Further, rⱼⁱ may be obtained using the formula

(r₀^{α}, r₁^{α}, r₂^{α}, . . . , rₖ₋₁^{α})=(0,α, 2α, . . . , (k−1)α), α=0,1,2, . . . , n−k−1

At step 206, data may be stored in each node in accordance with the nodes, represented by Nᵢ(i=0,1, . . . , n−1), corresponding to s₀, s₁, s₂, . . . , sₖ₋₁, m₀, m₁, m₂, . . . , mₙ₋ₖ₋₁, respectively.

For example, when n=6 and k=3, the coding identifiers may be represented by

ID =(0,0,0), ID₁=(0,1,2), ID₂=(0,2,4). Further, each original data block is represented by sᵢ=s_{i,1}s_{i,2} . . . s_{i,L} wherein, i=0,1, 2, . . . , k−1, and each parity data block is represented by mᵢ=m_{i,1}m_{i,2} . . . m_{i,L} wherein, i=0, 1, 2, . . . , n-k−1.

In an embodiment, the parity data block may be calculated as follows

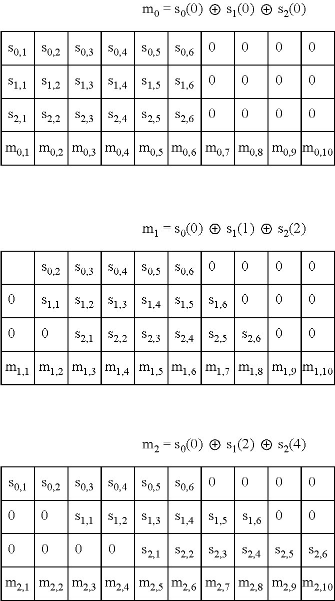

In an embodiment, the refreshing process of the BRS codes may be as follows:

When the original data changes, it is required to refresh the parity data blocks in order to keep the data consistent. During the encoding process, each parity data block may be calculated using the formula

$${m}_{i} = {\sum }_{j = 0}^{n - k - 1} {s}_{j} ( {r}_{j}^{i} )$$

Further, given that S=(s₀, s₁, . . . , sₖ₋₁) are changed to S′=(s′₀, s′₁, . . . , s′ₖ₋₁) increment may be calculated using the formula

ΔS=S′⊕S=(s₀⊕s′₀, s₁⊕s′₁, . . . , sₖ₋₁⊕s′ₖ₋₁=(Δs₀, Δs₁, . . . , Δsₖ₋₁)

Further, an increment of the parity data block may be calculated using the formula

$$Δ {m}_{i} = {m}_{i}^{′} ⊕ {m}_{i} = {\sum }_{j = 0}^{n - k - 1} ( {s}_{j}^{′} ( {r}_{j}^{i} ) ⊕ {s}_{j} ( {r}_{j}^{i} ) ) = {\sum }_{j = 0}^{n - k - 1} Δ {s}_{j} ( {r}_{j}^{i} )$$

Further, given that only sⱼ changes while others remain the same, that is, not all Δsⱼ are equal to zero, others are equal to zero, then Δmᵢ=Δsⱼ(rⱼⁱ), thereby m′ᵢ=mᵢ⊕Δsⱼ(rⱼⁱ). Thus, for each mᵢ, when one bit in S changes, it is only required to change the corresponding single bit in each mᵢ to realize the refreshing. Thus, the optimal refreshing complexity is reached.

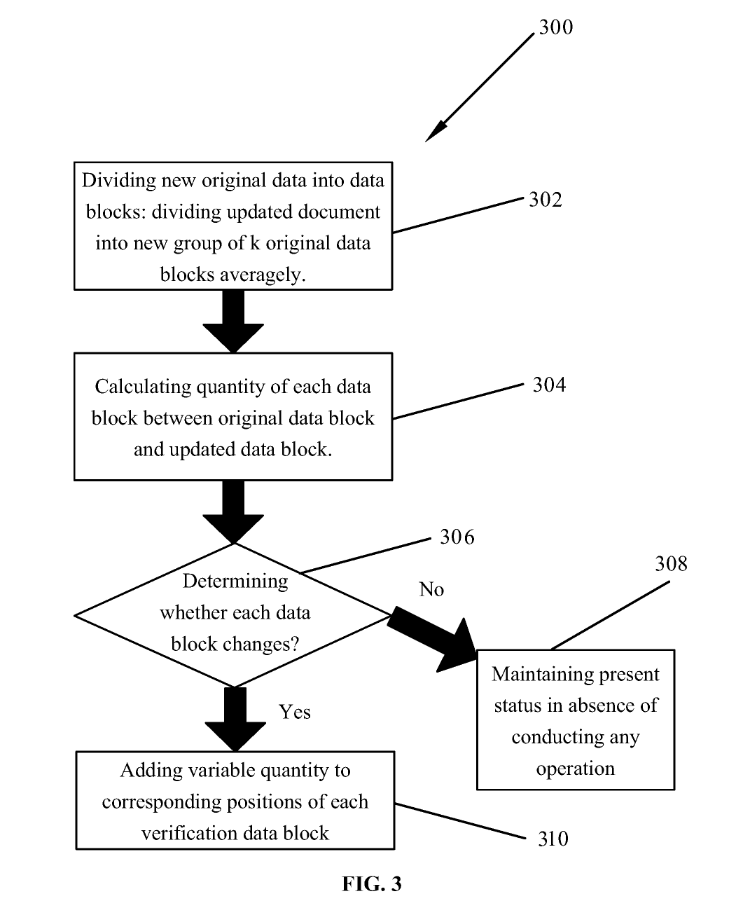

FIG. 3 is a flow chart 300 illustrating the refreshing process of the BRS code, in accordance with an embodiment. At step 302, the new original document is divided into data blocks, i.e. the updated documents are divided into new group of k original data blocks. At step 304, a variable quantity of each data block is calculated by comparing the original data blocks derived after refreshing with the corresponding original data bocks derived before refreshing.

At step 306 it is determined whether each data block changes, i.e., determining whether all the variable quantities are equal to zero. In case of determining no change to a data block, at step 308, a present status is maintained without conducting any operation. Further in case of determining a change to the data block, at step 310, the variable quantity Δs is added to the corresponding positions of each parity data block according to a redundant symbol.

In an embodiment, the reconstruction process of BRS code may comprises of the following steps: the BRS code is different from the general Reed-Solomon code as it only adopts the simple XOR operation and is able to realize multiplication independent of a finite field. In case of reconstructing the data, it is required to collect arbitrary k data blocks, and once damages are identified on the original data block, the parity data block may be adopted to perform the decoding calculation.

In an exemplary embodiment, to illustrate the reconstruction process of the BRS code, assuming that two original data blocks s₀ and s₁ are provided. The two parity data blocks are calculated using m₀=s₀(0)⊕s₁(0), m₁=s₀(0) ⊕s₁(1) is generated and a BRS code (n=4, k=2) is formed. During the reconstruction process, data blocks on two nodes are collected. In case, one data block is the original data block and the other data block is the parity data block, another original data block can be acquired by direct XOR operation according to

$${m}_{i} = {\sum }_{j = 0}^{n - k - 1} {s}_{j} ( {r}_{j}^{i} ) .$$

In case, the two data blocks are both the parity data blocks, then m₀=s₀(0) ⊕s₁(0) and m₁=s₀(0) ⊕s₁(1). Given that the values of a jth bit of each data block are s_{0,j}, s_{1,j}, m_{0,j}, m_{1,j}, respectively, according to the encoding process, m_{1,1}=s_{0,1}, m_{0,j}=s_{0,j}⊕s_{1,j}, m_{1,j+1}=s_{0,j+1}⊕s_{1,j}, j≧1, then all bits in s₀ and s₁ can be decoded by conducting XOR operations by cyclic iteration.

The encoding process of the BRS code in conditions of n=6 and k=3 are introduced in the above example. In case, three original data blocks are damaged, three parity data blocks are adapted to decode data. The following relations during encoding may be adopted:

m_{2,1}=s_{0,1}, m_{2,2}=s_{0,2},

m_{1,1}=s_{0,1}, m_{1,2}=s_{0,2}⊕s_{1,1}

Thus, s_{0,1}s_{0,2}, s_{1,1} are directly acquired. Then based on the following relations:

m_{0,i}=s_{0,i}⊕s_{1,i}⊕s_{2,i}

m_{1,i+2}=s_{0,i+2}⊕s_{1,i+1}⊕s_{2,i}

m_{2,i+4}=s_{0,i+4}⊕s_{1,i+2}⊕s_{2,i}

where i≧1,

Further, the following iteration formulas may be acquired:

s_{0,i}=m_{2,i}⊕s_{1,i-2}⊕s_{2,i-4}

s_{1,i-1}=m_{1,i}⊕s_{0,i}⊕s_{2,i-2}

s_{2,i-1}=m_{0,i-1}⊕s_{0,i-1}⊕s_{1,j-1}

,where i≧2 and s_{1,b}=S_{2,b}=0, (b≦0).

According to the above iteration formulas, values of three bits i.e., one bit of each of s₀, s₁, s₂ , may be calculated while performing each cycle. As each original data block has a length of L bits, all unknown bits of the original data block may be calculated after performing L cycles. Hence, the data reconstruction is accomplished.

Performance Evaluation of BRS Codes:

1. Computational Complexity of Encoding:

Row Diagonal Parity (RDP) code contains two parity data blocks. The first parity data block is acquired by XOR operation of k original data blocks. Each data block has a length of L bits, subsequently, (k−1)L number of XOR operations are required. The second parity data block is acquired by the XOR operation of k data blocks at pandiagonal lines, and (k−1)L number of XOR operations are required. Thus, the encoding complexity of the RDP code is optimal.

Cauchy Reed-Solomon (CRS) code has a packet number called “w”. The unoptimized encoding requires approximately

$$\frac{w}{2} ( k - 1 ) L$$

bit XOR operations. After the optimization, an average XOR calculation amount of each parity data block can reach approximately

$$\frac{w + 1}{4} ( k - 1 ) L$$

bits. However, in practical condition if w≧log₂n, then w≧4 (n≧9), thus during the encoding, the number of XOR operations of each parity data block must be larger than (k−1)L. Thus, the encoding complexity of the CRS code is not optimal.

In BRS code, the system has a total of n-k parity data blocks. Each parity data block is obtained by XOR operation of the k original data blocks. Thus, the system requires (k−1)L XOR operations to calculate each parity data block. The encoding complexity of the BRS code is optimal.

2. Computational Complexity of Decoding

The RDP code is decoded by iteration and, by itself, does not relate to the calculation of the finite field. Assuming that a fault number of the original data block is r (r≦2) , then the required calculation amount of the XOR operation is r(k−1)L bit.

The CRS code adopts the binary matrix to avoid the finite field calculation and at the same time accelerate the calculating speed. However, the encoding is determined by the binary matrix, an average XOR operations amount during the encoding is approximately

$$\frac{w}{2} r ( k - 1 ) L$$

bit. As generally w>3, the CRS code can realize the optimal encoding.

Like the RDP code, the BRS code is encoded by iteration and, by itself, does not relate to the calculation of the finite field. Given that the fault number of the original data block is r (r≦n−k) , subsequently the required calculation amount of the XOR operation during the reconstruction is r(k−1)L.

3. Computational Complexity of Refreshing

Although the RDP code is optimal in its encoding and decoding process, the refreshing process thereof is troublesome. Once one bit of the original data changes, the parity data block obtained by the XOR operation of data in rows requires the refreshing of only one bit, while the parity data block obtained by the XOR operation of data in pandiagonal lines requires the refreshing of two bits since the parity data block obtained by the XOR operation of data in pandiagonal lines is dependent on both the original data block and the parity data block obtained by the XOR operation of data in rows. Thus, in order to refresh one bit, an average of 1.5 bits are required to be refreshed for each parity data block.

The encoding process of the CRS code is optimized, but the optimization of the refreshing process thereof is difficult to realize. The refreshing complexity of the CRS code is closely related to the binary matrix thereof. On an average, each parity data block requires to refresh approximately

$$\frac{w}{2}$$

bits for every one bit that needs to be refreshed.

The refreshing process of the BRS code may be similar to the encoding process. In encoding, since every bit of the original data is only used once, when one bit of the original data changes, it only requires the change of one corresponding bit of each parity data block to finish the data refreshing. When compared with the RDP code and the CRS code, the BRS code has a superior refreshing complexity. Also, the BRS code reaches the optimal refreshing complexity.

TABLE 1
Comparison of
computational complexity among CRS code and Triple-Star code

| | CRS | RDP | BRS |
|---|---|---|---|
| Encoding complexity | $\frac{w + 1}{4} ( k - 1 ) L$ | (k − 1)L | (k − 1)L |
| Decoding complexity | $\frac{w}{2} r ( k - 1 ) L$ | r(k − 1)L | r(k − 1)L |
| Refreshing complexity | $\frac{w}{2}$ | $\frac{3}{2}$ | 1 |

L represents a size of an original document, and k represents a node number of a system.
‘r’ represents a number of damaged original data during decoding.
Values in the table represent bit numbers requiring XOR operation.
In CRS code, the computational complexities are all approximate values, and w represents a size of each group and satisfies w ≧ log₂ n.
In RDP code, k + 1 must be a prime number.

Compared to the Reed-Solomon code, the BRS code is advantageous in that the computational complexity is greatly decreased during the encoding and decoding processes. The XOR operation, which is simple and easy to implement is adopted, and the relative complicated operation of the finite field is avoided. The conventional construction of the Reed-Solomon code is based on the finite field GF(q), and the encoding process is related to the addition, subtraction, and multiplication of the finite field. Although the operation of the finite field has mature theoretical study, the practical application thereof is relatively troublesome and time consuming, and obviously cannot satisfy the fast and reliable design indicator of the distributed storage system. While the BRS code is different, its encoding operation and decoding operation are only limited to the fast XOR operation which greatly improves the upload rate and the download rate of the data and decreases the operation complexity of the system to a large degree (such as the refreshment of the metadata and the broadcasting of the refreshed data). The BRS code has great application value and development potential in the practical distributed storage system, and possesses an optimal encoding and decoding rate as well as the fastest refreshing speed. In case of huge data, the BRS code is able to finish the refreshment with its fastest speed and is able to accomplish the task faster, saving time and resource. The cost is decreased and a good user experience is also achieved.

The BRS code is able to ensure that its data storage of each node is as small as other Reed-Solomon codes. The BRS code also possesses the MDS attribute that enables the system to accommodate multiple node faults, thereby avoiding data loss. The BRS code is able to realize the accurate repair of the node, that is, the repaired data of the system is completely consistent to the lost data of the node, which makes the BRS code easy to implement and reduces the cost for the refreshing.

While particular embodiments of the invention have been shown and described, it will be obvious to those skilled in the art that changes and modifications may be made without departing from the invention in its broader aspects, and therefore, the aim in the appended claims is to cover all such changes and modifications that fall within the true spirit and scope of the invention.

The invention claimed is:

1. A method for encoding and decoding of data based on binary Reed-Solomon codes, the method comprising:
a) constructing binary Reed-Solomon codes from an original data using XOR operations;
b) refreshing the binary Reed-Solomon codes using XOR operations; and
c) reconstructing the binary Reed-Solomon codes using XOR operations.

2. The method of claim 1, wherein
the original data comprises k original data blocks;
each of the k original data blocks has a length of L bits and is expressed by the formula sᵢ=s_{i,1}s_{i,2} . . . s_{i,L}, i=0, 1, 2, . . . , k−1, a parity data block ‘mₐ’ is expressed by the formula mₐ=s₀(r₀)⊕s₁(r₁)⊕ . . . ⊕sₖ₋₁(rₖ₋₁), a unique identifier ‘IDₐ’ of the parity data block ‘mₐ’ is expressed as
ID_{α}=(r₀^{α}, r₁^{α}, . . . , rₖ₋₁^{α})=(0,α, 2α, . . . , (k−1)α), α=0,1,2, . . . , n−k−1,
the original data blocks and parity data blocks are linearly independent from one another; and
the original data blocks are stored in system nodes, and the parity data blocks are stored in verification nodes.

3. The method of claim 2, wherein 1) comprises:
dividing the original data into k original data blocks, wherein each original data block contains L bits of data, and the k original data blocks are expressed by S=(s₀, s₁, . . . , sₖ₋₁);
constructing parity data blocks using M=(m₀, m₁, . . . ,mₙ₋ₖ₋₁),
$${m}_{i} = {\sum }_{j = 0}^{n - k - 1} {s}_{j} ( {r}_{j}^{i} ) ,$$
i=0,1, . . . , k−1, in which rⱼⁱ represents a bit number of “0” added in front of sⱼ thereby forming the parity data blocks mᵢ, and rⱼⁱ is expressed as (r₀^{α}, r₁^{α}, r₂^{α}, . . . , rₖ₋₁^{α})=(0,α, 2α, . . . , (k−1)α), α=0,1,2, . . . , n−k−1; and
storing a total of N original data blocks with the parity data blocks to N nodes respectively, wherein the nodes Nᵢ(i=0,1, . . . , n−1) are stored with data s₀, s₁, s₂, . . ., sₖ₋₁, m₀, m₁, m₂, . . . ,mₙ₋ₖ₋₁ respectively, and the parity data blocks are acquired using XOR operation.

4. The method of claim 1, wherein 2) comprises:
refreshing a document and dividing a refreshed document into k original data blocks;
calculating a variable quantity of each data block by comparing the original data block derived after the refreshing, with the corresponding original data block derived before the refreshing; and
when the data block changes, adding a variable quantity to a corresponding position of each parity data block according to a redundant symbol, thereby refreshing the codes.

5. The method of claim 4, further comprising: when the data block does not change, maintaining a present status of the data block.

6. The method of claim 1, wherein 3) comprises:
collecting original data blocks and/or parity data blocks from arbitrary k nodes; and
performing XOR operations by cyclic iteration to decode the data.
